(19) United States
(12) Patent Application Publication
(10) Pub. No.: US 2025/0313939 A1
(43) Pub. Date: Oct. 9, 2025

(54) Method of Forming Bismuth Chalcogenide Film, Terahertz Detector Having Such a Film and Method of Forming Such a Detector

(71) Applicant: City University of Hong Kong, Kowloon (HK)

(72) Inventors: Johnny Chung Yin Ho, Shatin (HK); Yuxuan Zhang, Kowloon (HK); You Meng, Kowloon (HK)

(21) Appl. No.: 19/172,810

(22) Filed: Apr. 8, 2025

Related U.S. Application Data
(60) Provisional application No. 63/631,555, filed on Apr. 9, 2024.

(51) Int. Cl. C23C 14/06; C23C 14/24; C23C 14/58; G01J 1/42

(52) U.S. Cl. CPC C23C 14/0623; C23C 14/24; C23C 14/5806; G01J 1/4228

(57) ABSTRACT

A method of forming a bismuth chalcogenide film is disclosed including the steps of (a) forming at least one bismuth (Bi) elemental layer on a substrate, (b) forming at least one selenium (Se) or tellurium (Te) elemental layer on the substrate, and (c) after steps (a) and (b), heating the substrate to form a bismuth chalcogenide film.

### FIELD OF THE INVENTION

The present invention relates to a method of forming a bismuth chalcogenide film, a terahertz (THz) detector with such a film, and a method of forming such a detector.

### BACKGROUND OF THE INVENTION

The terahertz (10¹² hertz, THz) region is roughly defined as electromagnetic waves with wavelengths between 30 μm and 3 mm. As the last segment of the electromagnetic spectrum resource that has not yet been massively exploited, THz waves have profound research significance and broad application prospects not only in basic research fields such as wave-matter interaction, but also in application technology fields such as security inspection, communication, astronomy, atmospheric observation, and biomedicine. The frequency of THz waves is higher than that of microwaves and lower than that of infrared. In this transition area, neither the emission nor the detection of THz waves is entirely suitable for treatment with optical theory or research with microwave theory. Because of its special position, this frequency range possesses many unique properties. Firstly, THz waves can penetrate most dry, non-conductive media, and its energy is low, so it is not easy to cause ionization damage to the detected object. Therefore, it can perform perspective imaging on materials that are opaque to microwaves or visible light, and it is an effective complement to X-ray and ultrasound imaging. This makes THz radiation play a huge role in security and quality inspections. In addition, the frequency range contained in the THz band is very wide, and its carrier frequency can be two to three orders of magnitude higher than that of microwave radio. It can provide new means for point-to-point wireless communication far exceeding the current network speed.

However, many applications of optoelectronic technology in the visible or infrared bands cannot usually be directly converted to applications in the THz band. For example, in THz detection, traditional optoelectronic detectors used in the visible region usually use semiconductors as photosensitive materials. Their detection mechanisms are mainly photoconductive (PC) and photovoltaic (PV), which generally include the process of carrier inter-band transition. However, the energy of THz photons is much smaller than the energy of the band gap of the materials. This makes it difficult for these materials to serve as THz optoelectronic devices.

### SUMMARY OF THE INVENTION

According to a first aspect of the present invention, there is provided a method of forming a bismuth chalcogenide film, including steps (a) forming at least one elemental layer of bismuth (Bi) on a substrate, (b) forming at least one elemental layer of at least one chalcogen on said substrate, and (c) after said steps (a) and (b), heating said substrate to form a bismuth chalcogenide film.

In one embodiment the method further includes forming alternate elemental layers of bismuth and elemental layers of said at least one chalcogen on said substrate.

In one embodiment, said chalcogen is at least one of selenium (Se) and tellurium (Te).

In one embodiment, said bismuth chalcogenide is selected from a group consisting of Bi₂Se₃, Bi₂Te₃, and Bi₂Te₂Se.

In one embodiment, said step (a) is carried out by thermal evaporation.

In one embodiment, said step (b) is carried out by thermal evaporation.

In one embodiment, said step (a) is carried out in an evaporation chamber under high vacuum.

In one embodiment, said evaporation chamber is at a pressure of about 10⁻⁷ Torr.

In one embodiment, said step (c) is carried out by a rapid thermal process (RTP) or furnace annealing.

In one embodiment, said step (c) is carried out at a temperature from 150° C. to 400° C.

In one embodiment, said substrate is made at least principally of silicon, polyimide (PI), polyethylene terephthalate (PET) or polydimethylsiloxane (PDMS).

In one embodiment, said film can be rigid or flexible.

According to a second aspect of the present invention, there is provided a terahertz (THz) detector including a bismuth chalcogenide film.

In one embodiment, said bismuth chalcogenide film is formed by a method including steps (a) forming at least one elemental layer of bismuth (Bi) on a substrate, (b) forming at least one elemental layer of at least one chalcogen on said substrate, and (c) after said steps (a) and (b), heating said substrate to form a bismuth chalcogenide film.

In one embodiment, said detector is of a two-terminal structure or of an antenna structure.

In one embodiment, said detector is an antenna or a large-scale detector array.

According to a third aspect of the present invention, there is provided a method of forming a terahertz (THz) detector, including depositing electrode materials on a bismuth chalcogenide film.

In one embodiment, said bismuth chalcogenide film is formed by a method including steps (a) forming at least one elemental layer of bismuth (Bi) on a substrate, (b) forming at least one elemental layer of at least one chalcogen on said substrate, and (c) after said steps (a) and (b), heating said substrate to form a bismuth chalcogenide film.

In one embodiment, the method further includes pre-patterning said bismuth chalcogenide film for forming a large-scale detector array.

In one embodiment, said detector is an antenna or a large-scale detector array.

### BRIEF DESCRIPTION OF THE DRAWINGS

The patent or application file contains at least one drawing executed in color. Copies of this patent or patent application publication with color drawing(s) will be provided by the Office upon request and payment of the necessary fee. The present invention will now be more specifically described by way of examples only with reference to the accompanying drawings, in which:

FIGS. 1a and 1b show schematic views of steps of forming a bismuth chalcogenide film according to the present invention;

FIG. 2 shows a schematic view of the structure of a bismuth chalcogenide film according to the present invention;

FIG. 3 shows X-ray diffraction (XRD) spectra of a BizSes film after undergoing a rapid thermal process (RTP) at 300° C., according to the present invention;

FIG. 4a shows a high-resolution transmission electron microscopic (HRTEM) image of a film with elemental layers of bismuth (Bi) and selenium (Se) elemental layers deposited on a substrate prior to RTP;

FIG. 4b shows a selected-area electron diffraction pattern (SAED) of the film of FIG. 4a;

FIG. 4c shows an HRTEM image of the film of FIG. 4a after RTP at 300° C.;

FIG. 4d shows an SAED pattern of the film of FIG. 4c;

FIG. 5a shows an X-ray photoelectron spectroscopy (XPS) spectra of Bi 4f core levels of Bi₂Se₃;

FIG. 5b shows an XPS spectra of Se 3d core levels of Bi₂Se₃;

FIG. 6a shows the photodetection performance of a Bi₂Se₃ film based on a polyimide (PI) substrate measured at 0.3 THz irradiation and 0.1 mV bias;

FIG. 6b shows the corresponding high-resolution response of one switching on-off cycle with response time of 50 ms of the Bi₂Se₃ film based on a polyimide (PI) substrate;

FIG. 7 shows a schematic view of a THz detector with a bismuth chalcogenide film according to the present invention; and

FIGS. 8a, 8b, and 8c show schematic views of antennae with a bismuth chalcogenide film according to the present invention.

### DESCRIPTION OF THE PREFERRED EMBODIMENTS

The following describes the technical solutions in the embodiments of the present invention with reference to the accompanying drawings. Apparently, the described embodiments are merely some but not all of the embodiments of the present invention. All other embodiments based on the embodiments of the present invention and obtained by a person of ordinary skill in the art without investing creative efforts shall fall within the scope of the present invention.

In the present invention, the thermoelectric properties of bismuth chalcogenides (e.g., Bi₂Se₃, Bi₂Te₃, and Bi₂Te₂Se) and the photo-thermal effect of THz electromagnetic waves are employed to form the photo-thermoelectric (PTE) effect, which achieves the detection in the THz region. In particular, due to the unique PTE effect of bismuth chalcogenides, under the irradiation of THz waves, a device with a bismuth chalcogenide film will generate directionally moving hot carriers, forming a photoelectric signal.

In a broad sense, to prepare a bismuth chalcogenide thin film according to the present invention, thermal evaporation technology is used to alternately evaporate chalcogen (selenium (Se) and/or tellurium (Te)) elemental layers and bismuth elemental layers onto a substrate. Subsequently, the thin film is crystallized through rapid thermal treatment or conventional furnace annealing, where the heat treatment temperature can be controlled between 150° C. and 400° C. Without being intended to be limited by the theory, it is believed that the resulting bismuth chalcogenide thin film possesses semi-metallic properties, or has a minimal band gap, which meet the requirements of detection of THz electromagnetic waves (“THz detection”). A detector of THz electromagnetic waves (“THz detector”) with such a bismuth chalcogenide film can detect THz electromagnetic waves with a responsivity of 50 A/W and a response time of 50 ms.

The bismuth chalcogenide film according to the present invention is prepared by the stacked elemental layers of (i) bismuth (Bi) and (ii) one or more chalcogens (e.g., Se and/or Te), with a subsequent rapid thermal process (RTP) or conventional furnace annealing.

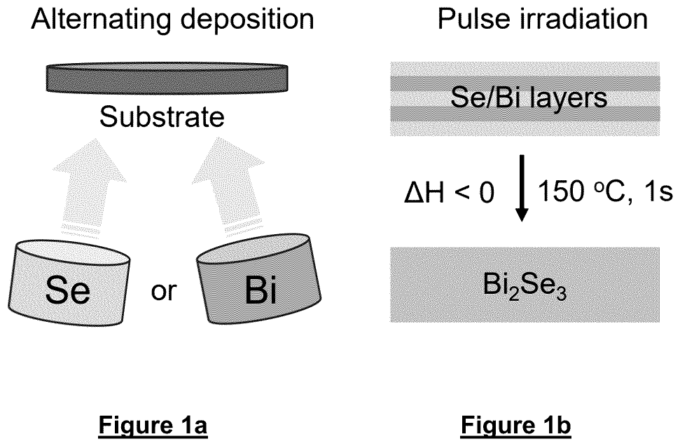

Detailed fabrication processes are summarized as follows:
1. As shown in FIG. 1a, elemental layers of at least one chalcogen (Se and/or Te) and bismuth (Bi) are evaporated onto a substrate in an alternating manner using a thermal evaporation system. The material sources are separately placed in individual tungsten boats in an evaporation chamber of the thermal evaporation system. The evaporation process is carried out under high vacuum (e.g., at a pressure of about 10⁻⁷ Torr) in the evaporation chamber.
2. After the evaporation chamber reaches the required vacuum level, the chalcogen element(s) is/are evaporated by controlling the power source.
3. After the evaporation of the chalcogen element(s) is completed, a shutter is used to protect the chalcogen source, and the bismuth source is opened to evaporate a bismuth layer on the substrate through the same process.
4. The thickness and speed of the elemental layer evaporation are monitored by a quartz crystal installed in the evaporation chamber, and the evaporation speed is about 1 Å/s.
5. As shown in FIG. 1b, the thin film with alternating elemental layers of Bi and one or more chalcogen(s) (Se in this particular example) is subjected to RTP or furnace annealing, and the temperature can be controlled at 150° C.˜400° C. For RTP, the processing time can be about 1 minute, and for furnace annealing, the processing time can be about 10 minutes. A Bi₂Se₃ film is thus formed.
6. Evaporate corresponding electrodes on the patterned thin film to form a THz detector or a large-scale detector array.
7. The antenna electrode structures could be designed and used to improve the device performance (e.g., butterfly antenna, parallel line antenna, and bow-tie antenna).

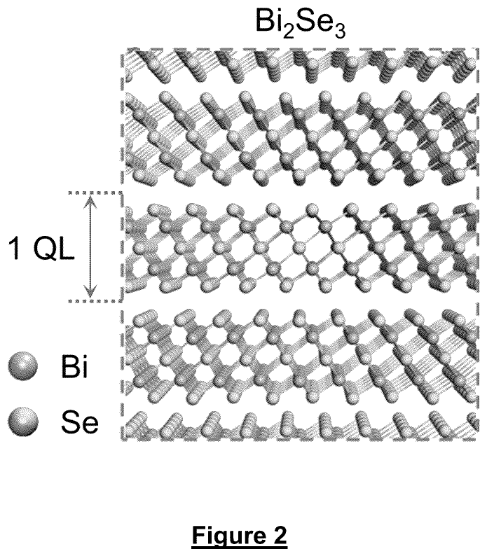

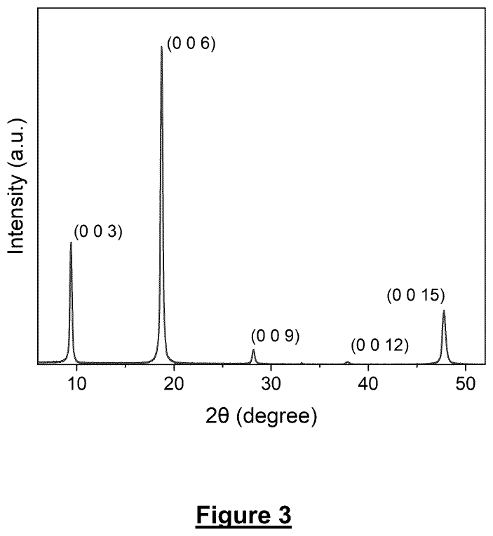

The deposition technique is compatible with various substrates, including silicon substrates and polymeric substrates (including polyimide (PI), polyethylene terephthalate (PET) and polydimethylsiloxane (PDMS) substrates). The crystalline temperature of Bi₂Se₃, Bi₂Te₃, or Bi₂Te₂Se ranges between 150° C. and 400° C. Therefore, the heat treatment temperature can be selected based on the maximum tolerance temperature of the substrate. A schematic view of the structure of a Bi₂Se₃ film according to the present invention is shown in FIG. 2, in which “QL” means “quintuple-layer.” Taking BizSes as an example, the XRD pattern shown in FIG. 3 reveals that the BizSes film has a uniaxial texture with crystallographic c-axis aligned along the substrate surface normal, which takes precedence over other directions. Peaks corresponding to out-of-plane orientations with (00I) (I=3, 6, 9, 12, 15) peaks are obvious after 300° C. RTP.

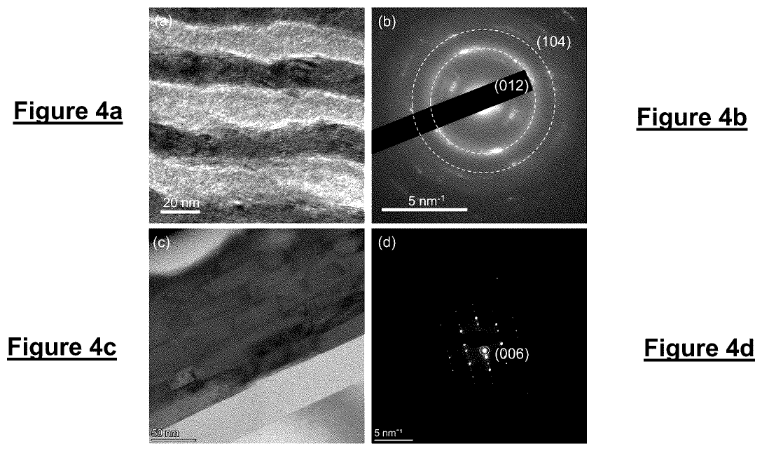

Images in FIGS. 4a to 4d further reveal the transformation process of the bismuth (Bi) and selenium (Se) elemental layers deposited on a substrate. First, FIG. 4a illustrates clear interfaces between Bi and Se elemental layers. The brighter layers represent selenium layers, while darker layers signify bismuth layers. As can be observed, the bismuth layers, which have not undergone any post-treatment, exhibit blurry lattice fringes, indicating that a certain degree of crystallization has occurred in the bismuth metal layers. This observation corresponds well with selected-area electron diffraction pattern (SAED) as shown in FIG. 4b, which reveals (012) and (104) diffraction rings of bismuth and the halo feature of amorphous Se phase. After RTP, well-crystallized bismuth selenide (Bi₂Se₃) is observed. As can be observed in FIG. 4c, the crystallized bismuth selenide thin film is formed by the stacking of numerous elongated grains. The continuous film is formed by means of grain coalescence through stacking, which may be ascribed to the alternating vapor deposition in this invention. In FIG. 4d, the SAED image clearly shows the layered structure of the BizSes thin films. Note that although the SAED pattern shows a single crystal structure, grain boundaries can be observed from a larger view, and crystals are oriented along the substrate surface normal, suggesting that the film is not a perfect single crystal.

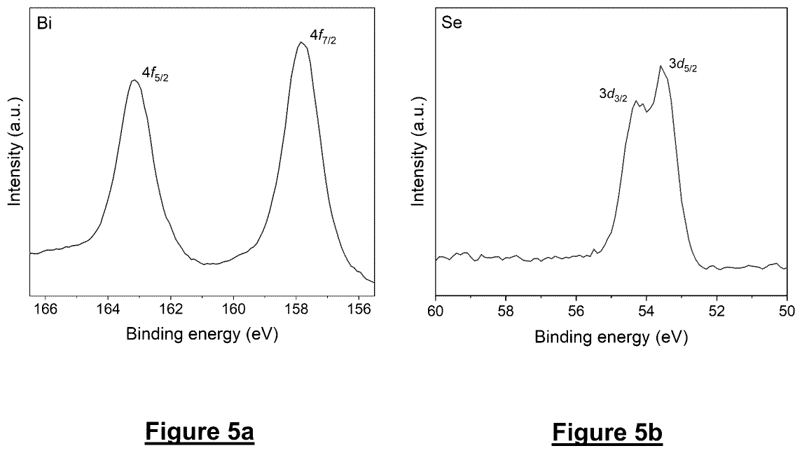

The surface composition of the BizSes film is characterized by the X-ray photoelectron spectroscopy (XPS), as shown in FIGS. 5a and 5b. Note that XPS is extremely sensitive to the surface state, as any adsorbate can influence the XPS result. Hence, a mild Ar+-etching was utilized before the XPS test. The XPS spectrum of bismuth in FIG. 5a exhibits Bi²⁺ 4f_{5/2} at 163.2 eV and 4f_{7/2} located at 157.8 eV, which corresponds to Bi²⁺ state in Bi₂Se₃. At the same time, no oxidized state of bismuth is observed in the RTP-treated film. In FIG. 5b, two XPS peaks of selenium 3d core levels can be observed, which further indicates the phase purity of the film.

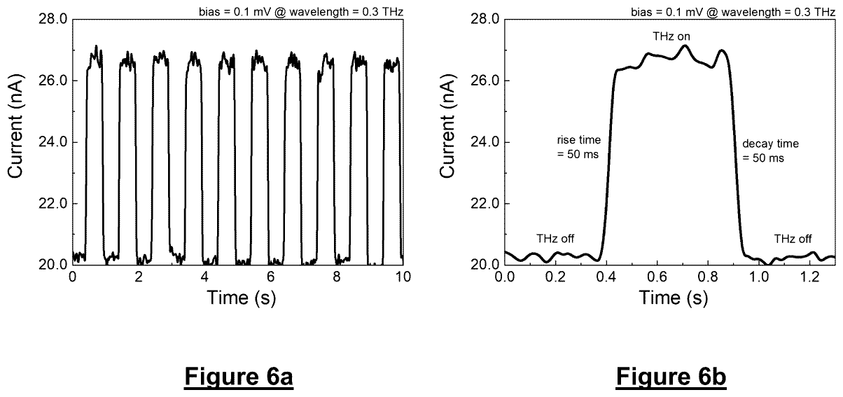

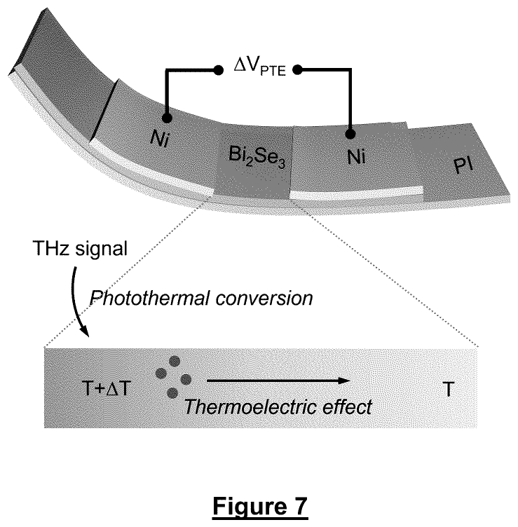

After the successful fabrication of bismuth chalcogenides on flexible substrates to form flexible films, their THz detection performance is investigated. A bismuth chalcogenide film with a proper band structure is used as the channel material of a THz detector, as shown in FIG. 7. Taking Bi₂Se₃ formed on PI substrates as an example, the Bi₂Se₃ devices exhibit excellent responsivity of 50 A/W and fast optical response in a switching measurement with 0.3 THz irradiation and 0.1 mV bias, as shown in FIG. 6a. At a chopping frequency of 1 Hz, the response times defined by the varying time for the photocurrent from 10% to 90% and from 90% to 10% are found to be 50 ms (rise time) and 50 ms (decay time), respectively (as shown in FIG. 6b). Overall, the obtained THz detection performance metrics including responsivity, response time and device durability are comparable to those THz detectors based on state-of-the-art materials. The THz detector according to the present invention possesses obvious photo-response in the THz range and the photo-response can be tuned via designing the device structure.

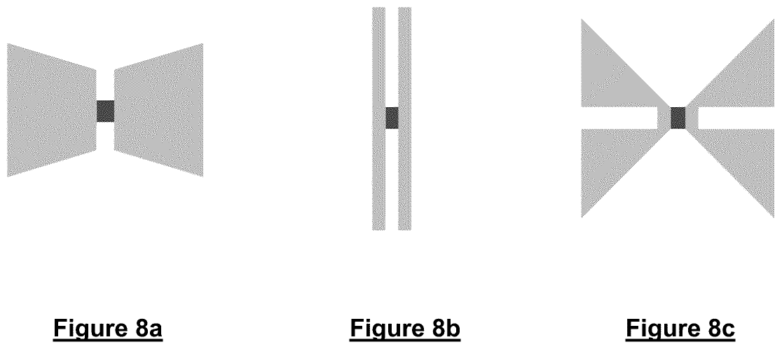

The THz detector according to the present invention may be adopted in a bow-tie antenna (see FIG. 8a), a parallel line antenna (see FIG. 8b) or a butterfly antenna (see FIG. 8c).

This invention successfully extends the frequency range of photoelectric detection from visible light and near-infrared to the THz wave range. The detection of the THz band is a feature that other photoelectric detector materials using traditional semiconductors find difficult to achieve. This invention holds significant implications for non-destructive testing of materials, pharmaceutical manufacturing, high-throughput wireless communication, and deep space exploration.

Most commercialized photodetectors on the market usually have limited detection spectra with complicated device structure. In this invention, combination of thermoelectric effect and photo-thermal effect empowers THz detection with a simplified device configuration. The fabrication strategy in this invention is also compatible with other photodetector devices, thus demonstrating its potential for the future development of flexible THz photodetectors. The substrate can be rigid or flexible, and the bismuth chalcogenide film formed with the substrate can therefore also be rigid or flexible, depending on the actual usage requirements.

The invention has brought about a prototype for the converting from light energy into thermal energy and ultimately into the electrical output for photodetectors. This achievement is based on the utilization of thermoelectric materials (which may be binary, ternary or quaternary) and the establishment of thermal couplings between substrates and films. The optimized PTE device delivers an outstanding THz photo-response, high responsivity (50 A/W for 0.3 THz), and fast response (<50 ms). This invention also enables the fabrication of large area photodetector array on multiple substrates with highly controllable performance.

It should also be understood that although the specification is described in terms of embodiments, not every embodiment includes only a single technical solution. This description of the specification is merely for the sake of clarity. Those skilled in the art should regard the specification as a whole, and the technical solutions in the embodiments can also be combined appropriately to form other embodiments that can be understood by those skilled in the art. However, the protection scope of the present invention is defined by the appended claims rather than the foregoing description, and it is therefore intended that all changes that fall within the meaning and scope of equivalency of the claims are included in the present invention and any reference signs in the claims should not be regarded as limiting the involved claims.

What is claimed is:

1. A method of forming a bismuth chalcogenide film, including steps:
(a) forming at least one elemental layer of bismuth (Bi) on a substrate,
(b) forming at least one elemental layer of at least one chalcogen on said substrate, and
(c) after said steps (a) and (b), heating said substrate to form a bismuth chalcogenide film.

2. The method of claim 1, further including forming alternate elemental layers of bismuth and elemental layers of said at least one chalcogen on said substrate.

3. The method of claim 1, wherein said chalcogen is at least one of selenium (Se) and tellurium (Te).

4. The method of claim 1, wherein said bismuth chalcogenide is selected from a group consisting of Bi₂Se₃, Bi₂Te₃, and Bi₂Te₂Se.

5. The method of claim 1, wherein said step (a) is carried out by thermal evaporation.

6. The method of claim 1, wherein said step (b) is carried out by thermal evaporation.

7. The method of claim 5, wherein said step (a) is carried out in an evaporation chamber under high vacuum.

8. The method of claim 7, wherein said evaporation chamber is at a pressure of about 10⁻⁷ Torr.

9. The method of claim 1, wherein said step (c) is carried out by a rapid thermal process (RTP) or furnace annealing.

10. The method of claim 1, wherein said step (c) is carried out at a temperature from 150° C. to 400° C.

11. The method of claim 1, wherein said substrate is made at least principally of silicon, polyimide (PI), polyethylene terephthalate (PET) or polydimethylsiloxane (PDMS).

12. The method of claim 1, wherein said film is flexible.

13. A terahertz (THz) detector including a bismuth chalcogenide film.

14. The detector of claim 13, wherein said bismuth chalcogenide film is formed by a method including the steps of:
(a) forming at least one elemental layer of bismuth (Bi) on a substrate,
(b) forming at least one elemental layer of at least one chalcogen on said substrate, and
(c) after said steps (a) and (b), heating said substrate to form a bismuth chalcogenide film.

15. The detector of claim 13, wherein said detector is of a two-terminal structure or of an antenna structure.

16. The detector of claim 13, wherein said detector is an antenna or a large-scale detector array.

17. A method of forming a terahertz (THz) detector, including depositing electrode materials on a bismuth chalcogenide film.

18. The method of claim 17, wherein said bismuth chalcogenide film is formed by a method including the steps of:
(a) forming at least one elemental layer of bismuth (Bi) on a substrate,
(b) forming at least one elemental layer of at least one chalcogen on said substrate, and
(c) after said steps (a) and (b), heating said substrate to form a bismuth chalcogenide film.

19. The method of claim 17, further including pre-patterning said bismuth chalcogenide film for forming a large-scale detector array.

17. he method of claim 17, wherein said detector is an antenna or a large-scale detector array.
